(19) United States
(12) Patent Application Publication
(10) Pub. No.: US 2021/0263155 A1
(43) Pub. Date: Aug. 26, 2021

(54) APPARATUS AND METHOD FOR OPTICAL SENSING USING AN OPTOELECTRONIC DEVICE AND OPTOELECTRONIC DEVICE ARRAYS

(71) Applicant: DOT9 INC, Lake Oswego, OR (US)

(72) Inventors: Drake Andrew MILLER, Lake Oswego, OR (US); Ren EARL, Salem, OR (US); Jeff Allan MCKEE, Springdale, UT (US)

(73) Assignee: DOT9 INC, Lake Oswego, OR (US)

(21) Appl. No.: 17/253,661

(22) PCT Filed: Jun. 18, 2019
(86) PCT No.: PCT/US19/37781

§ 371 Date: Dec. 18, 2020

Related U.S. Application Data
(60) Provisional application No. 62/686,530, filed on Jun. 18, 2018.
(60) Provisional application No. 62/686,532, filed on Jun. 18, 2018.
(60) Provisional application No. 62/686,539, filed on Jun. 18, 2018.
(60) Provisional application No. 62/686,543, filed on Jun. 18, 2018.
(60) Provisional application No. 62/686,547, filed on Jun. 18, 2018.

(51) Int. Cl. G01S 17/42; H01L 31/107; G01S 17/89; G01S 7/4863

(52) U.S. Cl. CPC G01S 17/42; G01S 7/4863; G01S 17/89; H01L 31/107

(57) ABSTRACT

Described is an optoelectronic device, comprising: a silicon material including a first doped region and a second doped region forming a high-field junction region; a reflective diffractive region coupled to and separated from the silicon material with a dielectric layer and positioned to interact with electromagnetic radiation; and a backside illuminated structure.

### BACKGROUND

Sensing of low-level signals of electromagnetic radiation is a benefit in all major technology driven industries. These industries include the medical, military, automotive, and commercial. Each of these industries has demanding requirements that push the edge of available technology. Silicon technology has been the workhorse of those industries driving the increasingly lowest-cost feature-rich products. Silicon, one of the most abundant elements on Earth, is used in crystal form as the substrate on which electronic circuits are fabricated as well as for the sensing and detection of optical wavelengths of electromagnetic radiation from the ultraviolet to the near infrared wavelengths. However, manufacturing of solid-state optical sensing devices made of Silicon has been a challenge for decades, in the near infrared wavelengths in the range of 750 to 1200 nanometer and more specifically in the 900 to 1200 nanometer wavelengths.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 illustrates a Light Detection and Ranging (LiDAR) system using embodiments of the present disclosure.

FIG. 2 illustrates a photon detection efficiency curve comparing current technology to an optoelectronic device of the present disclosure.

FIG. 3a illustrates an optoelectronic device according to some embodiments.

FIG. 3b illustrates a three dimensional (3D) view of an optoelectronic device, according to some embodiments.

FIG. 3c illustrates an optoelectronic device, according to some embodiments.

FIG. 3d illustrates an optoelectronic device, according to some embodiments.

FIG. 3e illustrates a 3D view of an optoelectronic device, according to some embodiments.

FIG. 3f illustrates an optoelectronic device, according to some embodiments.

FIG. 3g illustrates a 3D view of an optoelectronic device, according to some embodiments.

FIG. 4 illustrates an optoelectronic device array, according to some embodiments.

FIG. 4b illustrates an optoelectronic device array, according to some embodiments.

FIG. 4c illustrates an optoelectronic device array, according to some embodiments.

FIG. 5 illustrate an optoelectronic device according to some embodiments.

FIG. 6 illustrates an optoelectronic device array readout according to some embodiments.

FIG. 7 illustrates an optoelectronic device array logic according to some embodiments.

FIG. Xa-Xc illustrate schematics related to avalanche events, according to some embodiments.

FIG. X illustrates a system for range finding, according to some embodiments.

### DETAILED DESCRIPTION

Silicon is the most abundant material in use in the microelectronics industry and is the material of choice for microelectronics due to its many beneficial characteristics enabling high-volume manufacture, inexpensive material cost, and the ability to incorporate electronics with optically sensitive devices. Silicon can be used to make optoelectronic devices. The photo-response of silicon is from about 350 nm to 1200 nm. Optically sensitive silicon devices are typically responsive to light from the ultraviolet to the near-infrared. Typical optically sensitive devices in silicon have peak response in the 500 to 700 nm wavelength range. Common methods for increasing the sensitivity in the 700 to 1200 nm range, or often referred to as near infrared wavelengths, of electromagnetic radiation is through the use of thick absorption regions, increasing the generated signal through a multiplication of the absorbed carriers, or the use of alternative semiconductor materials that are more sensitive to this region of electromagnetic radiation.

Wavelengths in the near-infrared region are weakly absorbed in the material and typically require greater thickness to absorb the carriers due to the longer absorption depth of the near-infrared wavelengths. For instance, the 905 nm wavelength has an absorption depth of 50 microns. This makes absorption and therefore responsivity of this wavelength low in thin, less than 50 micron absorption regions. For that reason, typical optoelectronic device designs, optimized for near infrared light, traditionally use deeper junctions and/or thicker absorption regions, and higher bias voltages on the order of several tens to hundreds of volts to sweep the carriers to the semiconductor junction for collection. The drawback of such traditional device design is that the response time and timing jitter of the device is negatively impacted.

Silicon devices that use thick electromagnetic absorption regions to increase the sensitivity in the near-infrared will also suffer from increased time jitter and delay due to the longer transit time of the photo-generated carriers. In applications where high-speed response is a design requirement, there is a trade-off between sensitivity and speed. To optimize such a device, the sensitivity will often be what is given up, and consequently, an increase in the optical power or aperture size will be required to detect the desired signal. This is not advantageous for mobile or other power sensitive applications.

Another means for increasing the signal is through multiplication gain of the photo-generated charge carriers. One such technology that utilizes multiplication gain are avalanche photodiodes (APD). Avalanche photodiodes are operated in a region where the probability of one or both photo-generated charge carriers can cause an avalanche multiplication. An avalanche multiplication creates more than one charge carrier for each photo-generated carrier that initiates an avalanche. The APD is said to have a gain if it can generate more than one additional charge carrier. Multiplication gain for Silicon APD devices can be as high as 1000 or more. The advantage of this gain is that the signal is boosted before reaching noisy high-bandwidth electronics that provide additional signal conditioning. The drawback to the APD is that there is additional noise generated by the device called excess noise and the excess noise increases proportionally with the multiplication gain of the device. The excess noise can, under some conditions, be the noise limiting factor at high gain operation. Therefore, careful design practices must be followed to implement an APD correctly. In addition, avalanche photodiodes have a higher temperature sensitivity which causes a shift in the gain of the device during operation often requiring temperature stabilization. This is also not advantageous for mobile or other power sensitive applications.

An alternative to APDs is to use a material that is more sensitive in the near infrared. These materials include Germanium, Indium Gallium Arsenide, and others. These materials typically come from the III-V group of the periodic table. There are drawbacks to these materials. First, is that these materials are direct bandgap semiconductors and as such the dark current is higher as well as their temperature dependence on the dark current. The dark current is the current that flows through the device when no optical signal is present. Silicon can achieve dark current densities of less than or equal to 1 pA per cm² while III-V materials are typically in the single to double digit nA per cm² in state-of-the-art devices. This fact puts a fundamental limit on the capability of III-V material to sense weak electromagnetic radiation in the near infrared wavelengths. Second, these materials are typically more expensive to produce as they do not lend themselves to large scale manufacturing using Silicon. This again is not advantageous for mobile or other power sensitive applications.

The embodiments of the present disclosure provide optoelectronic devices and associated methods. In some embodiments, for example, an optoelectronic device includes a silicon material having an incident light surface, a first doped region and a second doped region forming a high field semiconductor junction operable above the avalanche breakdown voltage, and a region coupled to the semiconductor positioned to interact with electromagnetic radiation. In some embodiments, the optoelectronic device has a response time of 1 picosecond to about 1 nanosecond. The optoelectronic device is capable of generating a pulse at the output in response to incident electromagnetic radiation. The magnitude of the pulse indicates the detection of 1 or more photons for wavelengths from about 300 nm to 1200 nm. In another embodiment, the optoelectronic device generates a pulse, wherein the magnitude of the pulse indicates the reception of 1 or more photons for electromagnetic radiation having at least a wavelength in the range of 750 to 1200 nm. In another embodiment, the optoelectronic device generates a pulse, wherein the magnitude of the pulse indicates the reception of 1 or more photons for electromagnetic radiation having a wavelength in a range of 800 to 1100 nm. In a further embodiment, the Silicon material has a thickness of 1 micron to 50 microns. In another embodiment, the dark count rate from an optoelectronic device during operation is in the range of 0.01 Hz per micron² to 10 Hz per micron². In another embodiment, the timing jitter from an optoelectronic device is in the range of 1 ps to about 300 ps.

In one embodiment, for example, an optoelectronic device includes a silicon material having an incident light surface, a first doped region and a second doped region forming a high-field semiconductor junction operable above the avalanche breakdown voltage, and a region coupled to the semiconductor positioned to interact with electromagnetic radiation. The optoelectronic device has a response time of 1 picoseconds to 1 nanoseconds. The optoelectronic device is capable of generating a pulse at the output in response to incident electromagnetic radiation. The magnitude of the pulse indicating the reception of 1 or more photons for wavelengths of about 900 to about 1200 nm. In another embodiment, the PDE of the optoelectronic device is greater than 10% for a wavelength in the range of 900 to 1200 nm.

In another embodiment, for example, an optoelectronic device includes a silicon material having an incident light surface, a first doped region and a second doped region forming a high field semiconductor junction region operable above the avalanche breakdown voltage, and a region coupled to the semiconductor positioned to interact with electromagnetic radiation. The optoelectronic device has a response time of 1 picosecond to 1 nanosecond, for example. The optoelectronic device is capable of generating a pulse at the output in response to incident electromagnetic radiation. The magnitude of the pulse indicates the reception of 1 or more photons at wavelengths of about 905 nm. In another embodiment, the PDE of the optoelectronic device is in a range from 20% to about 50% for a wavelength of about 905 nm.

In another embodiment, for example, an optoelectronic device includes a silicon material having an incident light surface, a first doped region and a second doped region forming a high field semiconductor junction operable above the avalanche breakdown voltage, and a region coupled to the semiconductor positioned to interact with electromagnetic radiation. The optoelectronic device has a response time of 1 picosecond to about 1 nanosecond. The optoelectronic device is capable of generating a pulse at the output in response to incident electromagnetic radiation. The magnitude of the pulse indicates the reception of 1 or more photons at wavelengths of about 940 nm. In another embodiment, the PDE of the optoelectronic device is in a range from 20% to about 50% for a wavelength of about 940 nm.

In another embodiment, an optoelectronic device array includes a silicon material having an incident light surface, the array consisting of two or more pixel elements in the silicon material, each pixel element including one or more first doped regions and second doped regions forming one or more high field semiconductor junctions operable above the avalanche breakdown voltage, and at least one region coupled to the semiconductor positioned to interact with electromagnetic radiation. Each of the pixel elements having an independent signal output with a response time of 1 picosecond to about 1 nanosecond. The pixel element capable of generating a pulse at the output in response to incident electromagnetic radiation. The magnitude of the pulse indicates the reception of 1 or more photons at wavelengths in the range of 800 to 1200 nm.

In yet another embodiment, a method of decreasing the timing jitter of an optoelectronic device includes at least three doped regions in a silicon material with two of the doped regions forming at least one high field junction operable above the avalanche breakdown voltage, and a fourth region positioned to interact with electromagnetic radiation. The optoelectronic device has a response time in the range of about 1 picosecond to about 1 nanoseconds and the optoelectronic device generates a pulse at the output in response to incident electromagnetic radiation. The magnitude of the pulse indicates the reception of 1 or more photons at wavelengths in the range of 800 to 1200 nm. In one embodiment, the device includes a third doped region intended to quickly bring carriers from the side opposite the high field junction to the high field junction region. In another embodiment, the optoelectronic device has an additional doped region for moving carriers laterally to the high field junction region.

In another embodiment, a method is provided for increasing the PDE and decreasing the timing jitter and response time of an optoelectronic device. In some embodiments, least two optoelectronic devices are provided, where each optoelectronic device includes a first doped region and a second doped region forming a high field semiconductor junction operable above the avalanche breakdown voltage, and at least one region coupled to the semiconductor positioned to interact with electromagnetic radiation. The interaction of the electromagnetic radiation with the region causing lateral propagation of electromagnetic radiation in the semiconductor. The optoelectronic device has a response time of 1 picosecond to about 1 nanosecond. The optoelectronic device is capable of generating a pulse at the output due lateral propagation of secondary photons causing the avalanche of multiple adjacent devices where the pulse height is greater than the incident photon count. In another embodiment, the optoelectronic device is capable of generating a pulse at the output in response to 1 to about 10 photons of incident electromagnetic radiation where the pulse height is greater than the incident photon count.

One or more embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” or “some embodiments” means that a particular feature, structure, function, or characteristic described in connection with the embodiment is included in at least one embodiment of the invention. Thus, the appearances of the phrase “in an embodiment” or “in one embodiment” or “some embodiments” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

Note that in the corresponding drawings of the embodiments, signals are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

As a further embodiment, although not specifically covered by the diagrams or provided embodiments, it is understood that the invention will apply when combined with emerging technologies, that include but not limited to, applications where invention is bonded to other wafers singular and plural providing dual or mufti-function detectors i.e. visible merged with IR, bonded with digital or analog circuitry for enhanced functionality, electromagnetic or optical communication with other chips, embedded lasers, mirrors, or MEMs, arrays with variably tuned structures defined by architecture, input or output parameters, or process variance. Other embodiments include but not limited to multiple detector device types on a single substrate within an array of standalone. There are multiple ways to create or enhance an electric field in a device, all methods shall apply to the current invention although individual methods are not addressed.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The term “device” may generally refer to an apparatus according to the context of the usage of that term. For example, a device may refer to a stack of layers or structures, a single structure or layer, a connection of various structures having active and/or passive elements, etc. Generally a device is a three dimensional structure with a plane along the x-y direction and a height along the z direction of an x-y-z Cartesian coordinate system. The plane of the device may also be the plane of an apparatus which comprises the device. The Cartesian coordinates are shown in the figures with corresponding arrows, and the thicknesses described herein with respect to various embodiments are in the z-direction.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” and “on” as used herein refer to a relative position of one component or material with respect to other components or materials where such physical relationships are noteworthy. For example in the context of materials, one material or material disposed over or under another may be directly in contact or may have one or more intervening materials. Moreover, one material disposed between two materials may be directly in contact with the two layers or may have one or more intervening layers. In contrast, a first material “on” a second material is in direct contact with that second material/material. Similar distinctions are to be made in the context of component assemblies.

The terms “left,” “right,” “front,” “back,” “top,” and “bottom” and the like in the description and in the claims, if any, are used for descriptive purposes and not necessarily, for describing permanent relative positions.

The term “adjacent” here generally refers to a position of a thing being next to (e.g., immediately next to or close to with one or more things between them) or adjoining another thing (e.g., abutting it).

The term “circuit” or “module” may refer to one or more passive and/or active components that are arranged to cooperate with one another to provide a desired function.

The term “signal” may refer to at least one current signal, voltage signal, optical, magnetic signal, or data/clock signal. The meaning of “a,” “an,” and “the” include plural references. The meaning of “in” includes “in” and “on.”

The term “scaling” generally refers to converting a design (schematic and layout) from one process technology to another process technology and subsequently being reduced in layout area. The term “scaling” generally also refers to downsizing layout and devices within the same technology node. The term “scaling” may also refer to adjusting (e.g., slowing down or speeding up—i.e. scaling down, or scaling up respectively) of a signal frequency relative to another parameter, for example, power supply level. The terms “substantially,” “close,” “approximately,” “near,” and “about,” generally refer to being within +/−10% of a target value.

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

The term “between” may be employed in the context of the z-axis, x-axis or y-axis of a device. A material that is between two other materials may be in contact with one or both of those materials, or it may be separated from both of the other two materials by one or more intervening materials. A material that is between two other materials may be in contact with one or both of those materials, or it may be separated from both of the other two materials by one or more intervening materials, either temporally, spatially, in ranking or connected to one or both of those devices, or it may be separated from both of the other two devices by one or more intervening devices.

It is pointed out that those elements of the figures having the same reference numbers (or names) as the elements of any other figure can operate or function in any manner similar to that described, but are not limited to such.

The term “high-field junction” generally defined as a semiconductor junction comprising of 2 or more doped regions of opposite polarity forming a semiconductor junction operated with an electric field across the junction capable of causing carrier multiplication. Common types of optoelectronic devices employing a high-field junction during operation include: avalanche photodiodes (APDs), single-photon avalanche diodes (SPADs), silicon photo-multipliers (SiPM), and the like. In one embodiment, a high-field junction fabricated in silicon during operation has an electric field of greater than or equal to 1E5 V/cm.

The term “quantum efficiency” (QE) is generally defined as the percentage of photons incident on an optoelectronic device that are converted into electrons. External QE (EQE) is defined as the current obtained outside of the device per incoming photon. As such, EQE therefore depends on both the absorption of photons and the collection of charges. The EQE is lower than the QE due to recombination effects and optical losses (e.g. transmission and reflection losses).

The term “responsivity” is generally defined as a measure of the output current in response to the input optical power of a detector system. In the case of an optoelectronic device, responsivity is a measure of the electrical output per optical input. Responsivity of a photodetector is expressed in amperes per watt of incident radiant power. Additionally, responsivity is a function of the wavelength of the incident radiation and of the properties of the device, such as the bandgap of the material of which the device is made. One expression for responsivity (R(λ)) is shown in Equation I, where Iₚ is the average measured photocurrent at a given wavelength (λ), Pₒₚ is the incident optical power:

$$R ( λ ) = \frac{{I}_{p}}{{P}_{o p}} \qquad ( I )$$

Terms “electromagnetic radiation” and “light” can be used interchangeably, and generally represent wavelengths across a broad range, including visible wavelengths (e.g., approximately 350 nm to 800 nm) and non-visible wavelengths (e.g., longer than about 800 nm or shorter than 350 nm). The infrared spectrum is often described as including a near infrared portion of the spectrum including wavelengths of approximately 800 to 1300 nm, a short wave infrared portion of the spectrum including wavelengths of approximately 1300 nm to 3 micrometers, and a medium to long wave infrared (or thermal infrared) portion of the spectrum including wavelengths greater than about 3 micrometers up to about 30 micrometers. These are generally and collectively referred to herein as “infrared” portions of the electromagnetic spectrum unless otherwise noted.

The term “PDE” generally represents the photon detection efficiency of an optoelectronic device. Most commonly, PDE refers to an optoelectronic device that operates with an avalanche gain. PDE is a measure of the probability of detecting an incident photon. It is defined as:

PDE=η(λ)*k*FF; (II)

where η is the quantum efficiency as a function of wavelength of the device, and k is the electron-hole ionization ratio, and FF is the fill factor of the device.

Term “DCR” generally represents dark count rate of an optoelectronic device when operated above the breakdown voltage. DCR is a measure of the rate at which an avalanche pulse is generated at the output of the device in the absence of optical input.

The term “detection” generally refers to the actions of sensing, output signal threshold crossing, absorption, and/or collection of electromagnetic radiation.

The term “saturation velocity” generally refers to a velocity of charge carriers that are drifting in a sufficiently strong electric field for the charge carrier to be traveling at a velocity that does not increase with an increase in the electric field strength.

The term “response time” generally refers to the rise time or fall time of a detector device. In one embodiment, “rise time” is the time difference between the 10% point and the 90% point of the peak amplitude output on the leading edge of the electrical signal generated by the interaction of light with the device. “Fall time” is measured as the time difference between the 90% point and the 10% point of the trailing edge of the electrical signal. In some embodiments, fall time is referred to as the decay time.

The term “reflective diffractive region” generally refers to a region having diffractive and/or reflective characteristics to incident electromagnetic radiation. Diffraction of electromagnetic radiation is typically caused by the constructive and/or destructive interference of electromagnetic waves. In most cases, reflective diffractive region is ordered and has defined diffraction orders. In other cases, reflective diffractive region can have random orders and thus direct light passing off of or through the region in a disordered fashion. A region having diffraction characteristics can be made up of one or more of random, pseudo random, periodic, nano- to micron-sized features or a combination thereof. In addition, diffraction and field confinement can be caused by nanoparticles positioned to interact with electromagnetic radiation.

Nanoparticles are typically applied to surfaces using spin coating of a nanoparticle suspension or formed using metal evaporation and subsequent annealing techniques. Such a region can be formed by the irradiation of a laser pulse or laser pulses, chemical etching, lithographic patterning, interference of multiple simultaneous laser pulses, reactive ion etching, selective deposition, additive, subtractive and any combination of these or previously mentioned techniques. While the characteristics of such a diffractive region can be variable depending on the desired optical characteristics, materials, and techniques employed, in one embodiment, such a region includes micron-sized structures (e.g., about 1 μm to about 10 μm). In yet another embodiment, the region includes nano-sized and/or micron-sized structures in the range of 5 nm to 5 um. In another embodiment, the diffractive features are formed using nanoparticles to include but not limited to one or a combination of SiO2 nanospheres, silver nanoparticles, gold nanoparticles, aluminum nanoparticles, and the like.

In another embodiment, the region comprises of a surface and/or contained in or surrounded by another region. In another embodiment, the region comprises of metallic material capable of reflecting electromagnetic radiation. The metallic material comprises of any such metal sufficient for efficient reflection of electromagnetic radiation and commonly used in semiconductor manufacturing, such as aluminum, tungsten, gold, copper, titanium, silver, and the like. In another embodiment, the region comprises of 1 or more pairs of layers of high and low index materials designed to form a distributed Bragg reflector. In another embodiment, the region comprises of parabolic, spherical, or aspherical curved surfaces to focus or defocus the impinging electromagnetic radiation.

In an additional embodiment, the surface of the silicon of the device itself can be modified to produce the desired redirection of photon radiation. The use of the higher index of refraction of silicon provides a means to redirect light normal to the silicon surface. This modification includes but not limited to a target area that randomly distributes photon trajectories but can be modified to direct photons in a controlled specified trajectory. Random and specified trajectories can be incorporated in combination or independently. Embodiments previously presented can be incorporated in combination or independently with the current embodiment.

The term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained.

The use of term “substantially” is generally equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is generally used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually. This same principle applies to ranges reciting only one numerical value as a minimum or a maximum. Furthermore, such an interpretation should apply regardless of the breadth of the range or the characteristics being described.

The term “saturation velocity” generally refers to the velocity of charge carriers that are drifting in a sufficiently strong electric field for the charge carrier to be traveling at a velocity that does not increase with an increase in the electric field strength.

Increasing the sensitivity of an optoelectronic device has many benefits. One such benefit is the need to use less optical power and/or to detect very weak signals. Another benefit is size. With higher sensitivity the aperture size can be reduced without decreasing performance resulting in a smaller lighter more power efficient end-product. The reduction of laser power also has impacts on the electro-optical design of the transmitter system allowing for smaller emitters in the case of a semiconductor laser resulting in smaller more compact collimation optics. This has a benefit in many applications especially in Light Detection and Ranging (LiDAR) systems where low power and long range are desirable features.

Some embodiments allow for mobile compact LiDAR systems. One benefit of some embodiments is the decreased timing jitter of the device. One factor that affects the timing jitter of an optoelectronic device is caused by the position where the photoelectric carriers are generated and the magnitude of the electric field in the region where the carriers are absorbed in the semiconductor. Photoelectric carriers that are generated near a semiconductor junction will typically have a small transit time and a an electric field to transport them to the semiconductor junction resulting in lower timing jitter while the carriers absorbed further from the semiconductor junction in a lower field region will have longer to travel at a slower speed thereby increasing the timing jitter for carriers generated deeper in the semiconductor. Timing jitter places a limit on the distance resolution that can be obtained from the device in applications such as LiDAR. An optoelectronic device benefits from having a short transit time to the high field semiconductor junction, for the photoelectric carriers.

Optoelectronic devices have a variety of uses. For example, in one embodiment an array of device can be formed to make an imager. Numerous types of imagers are contemplated, and any such imager or imaging application is considered to be within the present scope. Non-limiting examples include 3D imaging, machine vision, night vision, security and surveillance, various commercial applications, laser range finding and LiDAR, and the like. Thus, in the case of 3D imaging for example, the imager is operable to detect a phase delay and/or time-of-flight between a reflected and an emitted optical signal.

As one example, various applications can benefit from depth information, such as drones, autonomous robotics and vehicles, hands-free gesture control, immersive reality devices, video games, medical applications, machine vision, etc. Time-of-flight (TOF) is a technique developed for use in radar and LIDAR (Light Detection and Ranging) systems to provide distance information. The basic principle of TOF involves sending a signal and measuring a property of the returned signal from a target. The measured property is used to determine the TOF.

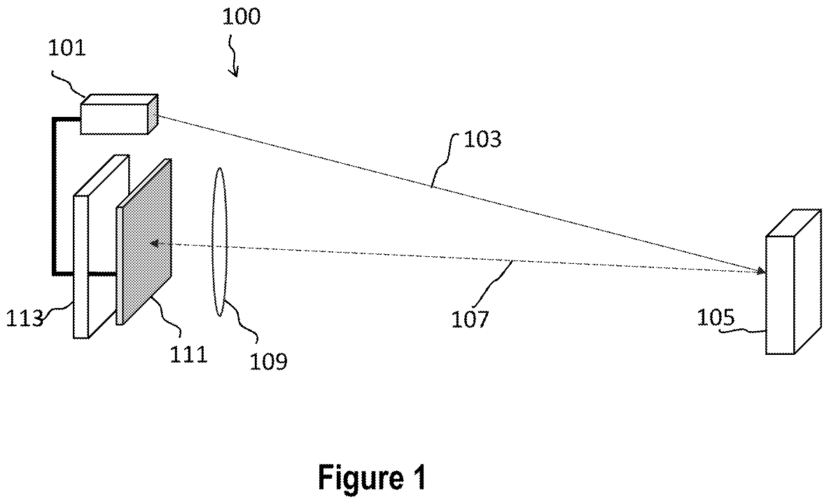

FIG. 1 illustrates a LiDAR system 100 comprising of 3 components: one or more transmitters 101, and one or more receivers 111, and one or more processing devices 113. In addition to these components, the transmitter comprises of a transmitter drive electronics and a beam shaping and collimation optics. In addition, a method for scanning the transmit beam can be employed to extend the angular extent in azimuth and elevation over which the transmit beam can interrogate and detect objects in the scene. Any method for scanning the beam is within the scope of the embodiments. For example, scanner(s) with resonant mirrors, optical phase arrays, diffractive liquid-crystal-on-silicon scanners, and the like are within the scope of the various embodiments.

In some embodiments, the scanner may be operable to scan in one dimension. In other embodiments, the scanner is operable to scan in two dimensions. In some embodiments, the beam shaping optics are designed such that a controlled divergence beam is formed such that there is one or more axis with the same or different divergence. For example, one axis has higher divergence than a lower divergence axis. In some embodiments, the higher divergence axis of one or more of the laser transmitters has a divergence of about 1 degree to about 5 degrees. In other embodiments, the higher divergence axis has a divergence of about 5 degrees to about 60 degrees. In some embodiments, the lower divergence axis has a divergence of about 0.01 degrees to about 0.1 degrees. In other embodiments, the lower divergence axis has a divergence of 0.1 to about 1 degrees. In some embodiments, the lower divergence axis has a divergence of 1 to about 10 degrees.

In some embodiments, the receiver 111 and transmitter 101 are operated with a processing system 113 for control, synchronization, and processing of the data received from the receiver. The output data of the processing system includes but is not limited to distance to objects, trigger signals, interrupt signals, object movement, reflectivity of objects, and pose of the system. Equation (III) is the driving equation of the direct time-of-flight measurement and is used to derive the distance from an object to the transmitter:

$$d = \frac{T O F}{2} \times c \qquad ( III )$$

where TOF is the round-trip time of flight, d is the distance to the target, and c is the speed of light.

By measuring the TOF from the emission from a transmitter 101, traveling to 103 an object 105 and from 107 an object, the distance from the transmitter to the surface of the object can be directly measured. In an imager configuration, each pixel element can perform the above TOF measurement, and a depth image of all objects detected in the field of view can be achieved. In addition to the direct TOF method, there are indirect TOF techniques which measure the phase difference between the transmitted and reflected beam.

Accordingly, some embodiments of the present disclosure provide optoelectronic devices and device arrays with high-field semiconductor junctions and associated methods that increase the PDE while maintaining the low timing jitter and response time of a thin silicon device when exposed to electromagnetic radiation in the near-infrared.

In one embodiment, an optoelectronic device is provided. Such an optoelectronic device includes a silicon material having one incident light surface, first doped region and a second doped region forming a high-field semiconductor junction in the silicon material, and a diffractive region coupled to the silicon material and positioned to interact with electromagnetic radiation. In some embodiments, the optoelectronic device has a timing jitter in the range of 1 ps to 500 ps and a PDE of greater than or equal to about 20% for electromagnetic radiation having at least a wavelength in the range of 750 nm to 1200 nm.

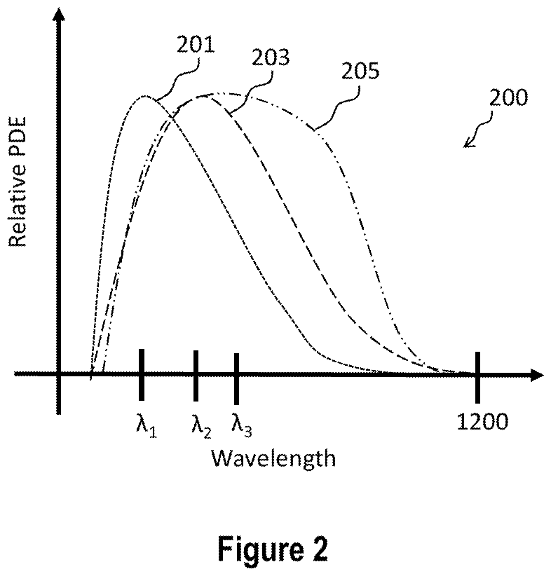

FIG. 2 illustrates a PDE versus wavelength graph 200 where the dashed line 201 represents the PDE of a standard device. The large dashed line 203 represents an optoelectronic device utilizing a thicker absorption region. The dashed dotted line 205 demonstrates the PDE of an optoelectronic device of the present disclosure. The peak wavelength of the representative devices is in the range of 400 nm to about 600 nm for a standard device 201, in the range of 500 nm to about 700 nm range for a thicker device 203, and 700 nm to about 1000 nm for an optoelectronic device of the present disclosure 205.

Additionally, in one embodiment the timing jitter of the optoelectronic device is in the range of 1 ps to 500 ps. In another embodiment, the timing jitter of the optoelectronic device is in the range of 1 ps to 100 ps.

In another embodiment, the optoelectronic device has a PDE of greater than 20% for electromagnetic radiation having at least a wavelength in the range of 750 nm to 1200 nm. In yet another embodiment, the optoelectronic device has a PDE greater than or equal to 20% for wavelengths of about 800 nm. In a further embodiment, the optoelectronic device has a PDE greater than or equal to 20% for wavelengths of about 905 nm. In a further embodiment, the optoelectronic device has a PDE greater than or equal to 20% for wavelengths of about 940 nm. In yet a further embodiment, the optoelectronic device has a probability of detection greater than or equal to 20% for wavelengths greater than or equal to about 1000 nm.

In some embodiments, the thickness of an optoelectronic device can dictate the PDE, DCR, timing jitter, and/or response time. As previously discussed, standard silicon optoelectronics devices need to be thick, e.g., greater than 100 μm in some cases, to detect wavelengths in the near infrared spectrum, and such detection with thick devices results in high timing jitter, long response times, and increased dark count rates. It has now been discovered that reflective diffractive regions positioned to interact with electromagnetic radiation can substantially increase the absorption of near infrared light in an optoelectronic device, thereby improving the PDE and DCR while simultaneously allowing for low timing jitter and short response time operation. Light diffraction and reflection can result in increased path lengths for absorption, particularly if combined with total internal reflection, resulting in large improvements of PDE in the near infrared for thin silicon optoelectronic devices utilizing high-field semiconductor junctions. Because of the increased path lengths for absorption, thinner silicon materials can be used to absorb near infrared electromagnetic radiation. In one embodiment, the silicon material thickness is in a range from 1 micron to about 50 microns. In another embodiment, the silicon material thickness is in a range from 5 microns to about 20 microns.

One advantage of thinner silicon material devices is that charge carriers are more quickly transported to the terminals of the device, thus decreasing the timing jitter. Furthermore, when an electric field is acting on the charge carriers, an additional increase in the carrier transport speed is realized reducing the timing jitter and response time. Conversely, thick silicon material devices absorb electromagnetic radiation throughout the device and must sweep the charge carriers from distances deeper and spread throughout the material, and even with the addition of an electric field to increase the transport, the charge carriers will arrive at the terminals in a larger spread of intervals increasing the timing jitter. In one embodiment, an optoelectronic device has a silicon material thickness in a range of 1 micron to about 50 microns and during operation the terminals of the device are biased in a range of 15V to about 40V. In another embodiment, during operation, the optoelectronic device is biased in a range of 10V to about 25V.

Thus, the optoelectronic devices of various embodiments increase the absorption of thin silicon materials utilizing high-field junctions by increasing the absorption path length for longer wavelengths as compared to traditional methods. The absorption depth in optoelectronic devices is the depth at which the electromagnetic radiation intensity is reduced by 1/e or 36% of the value at the surface of the material. The increased absorption path length results in an apparent reduction in the absorption depth, or a reduced apparent or effective absorption depth.

For example, the effective absorption depth of silicon can be reduced such that longer wavelengths can be absorbed at depths of less than or equal to about 50 μm. By increasing the absorption path length, such devices can absorb longer wavelengths (e.g. greater than 1000 nm for silicon) within a thin semiconductor material. In addition to decreasing the effective absorption depth, a benefit of some embodiments of the present invention is that the DCR, timing jitter, and response time can be decreased using thin semiconductor materials.

Accordingly, optoelectronic devices made of silicon according to embodiments of the present disclosure provide, among other things, significant increase in PDE in the near infrared and improve timing jitter and response time. As such, high PDE, low jitter, and low response time can be obtained in the near infrared wavelengths for silicon devices thinner than about 50 μm.

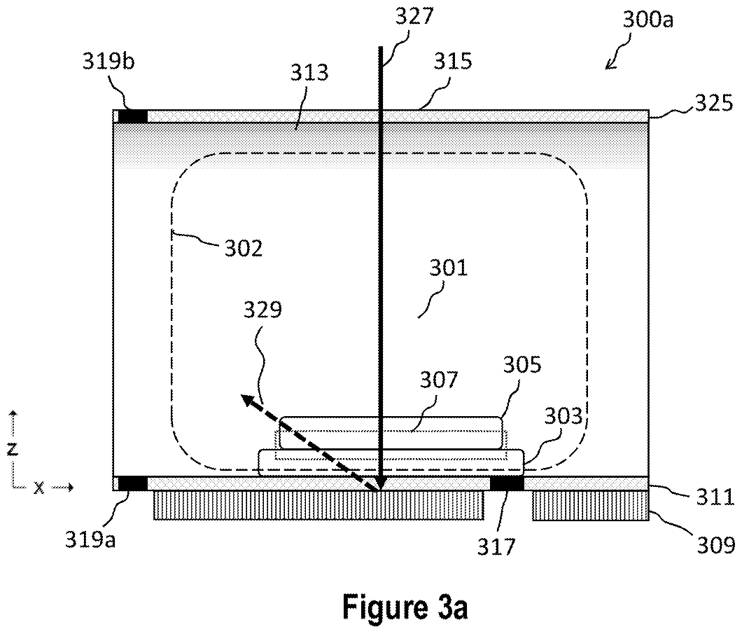

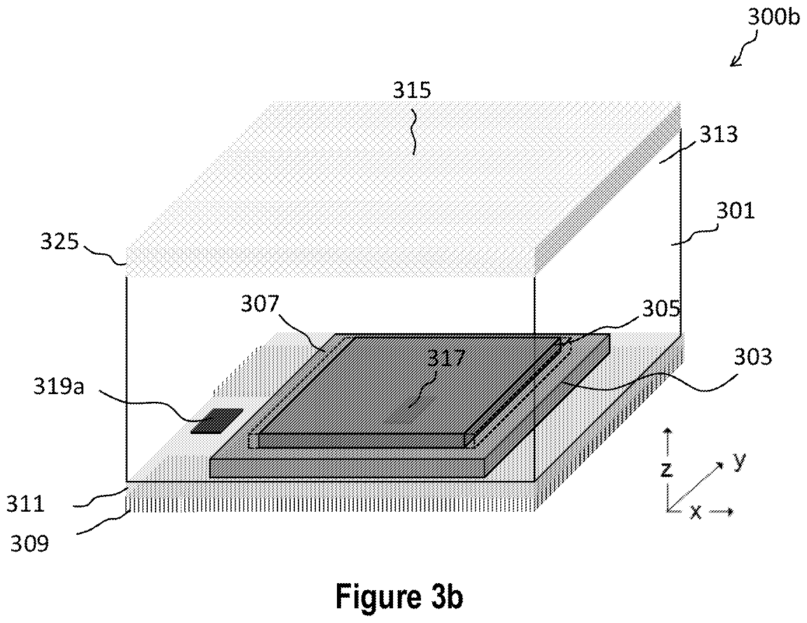

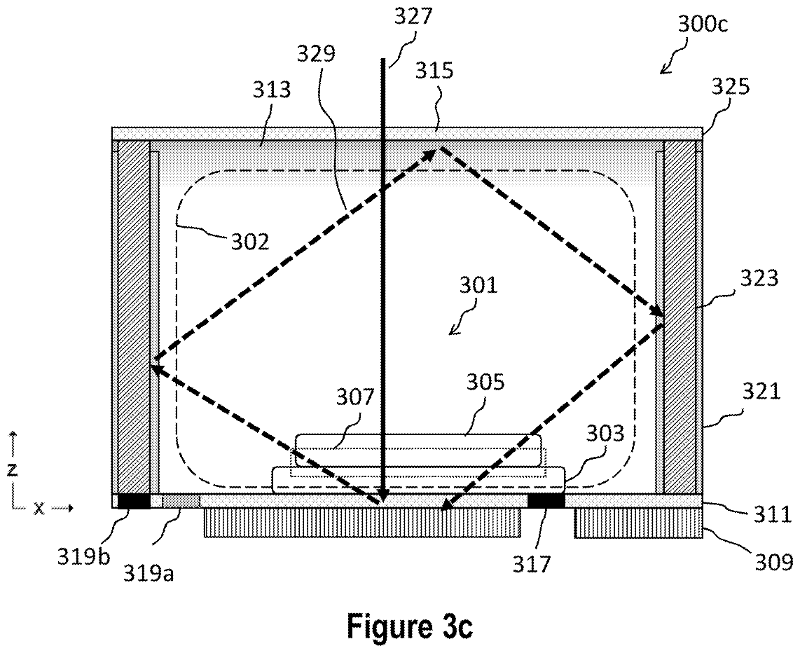

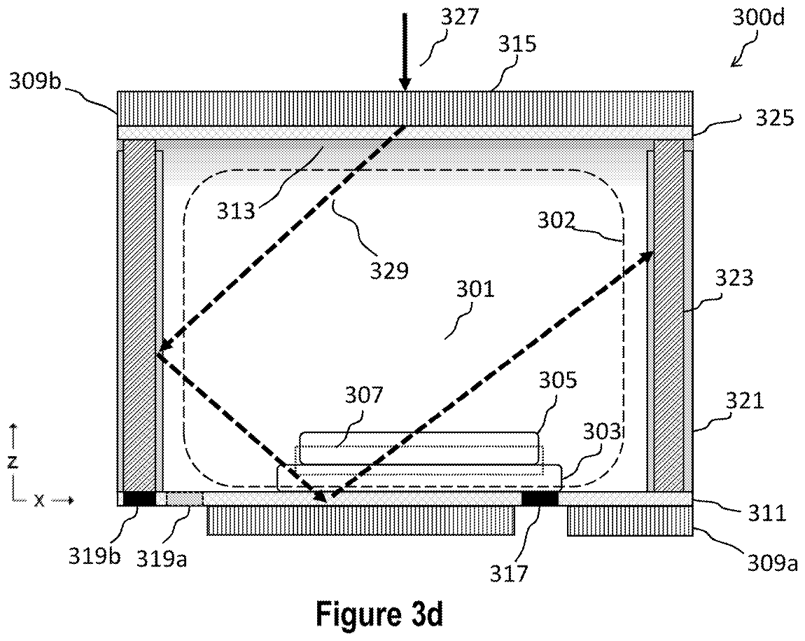

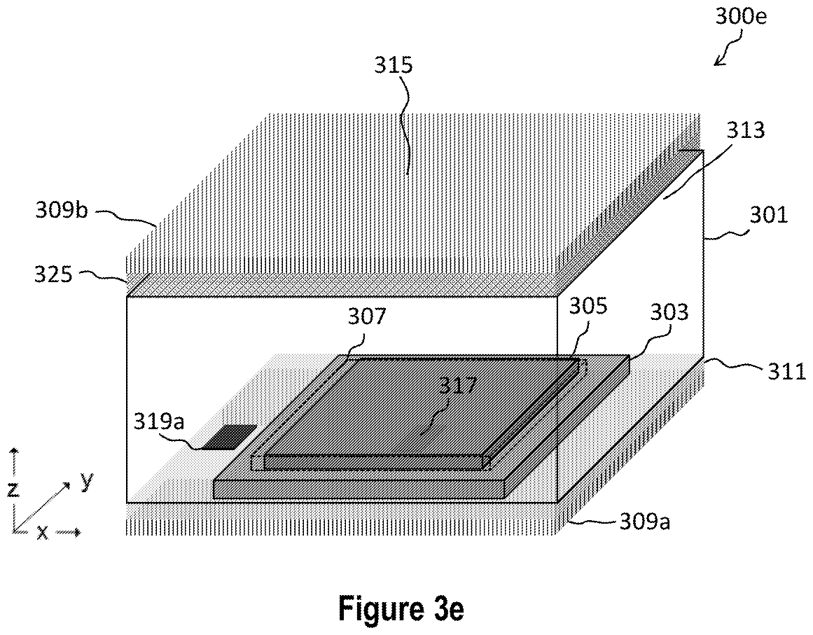

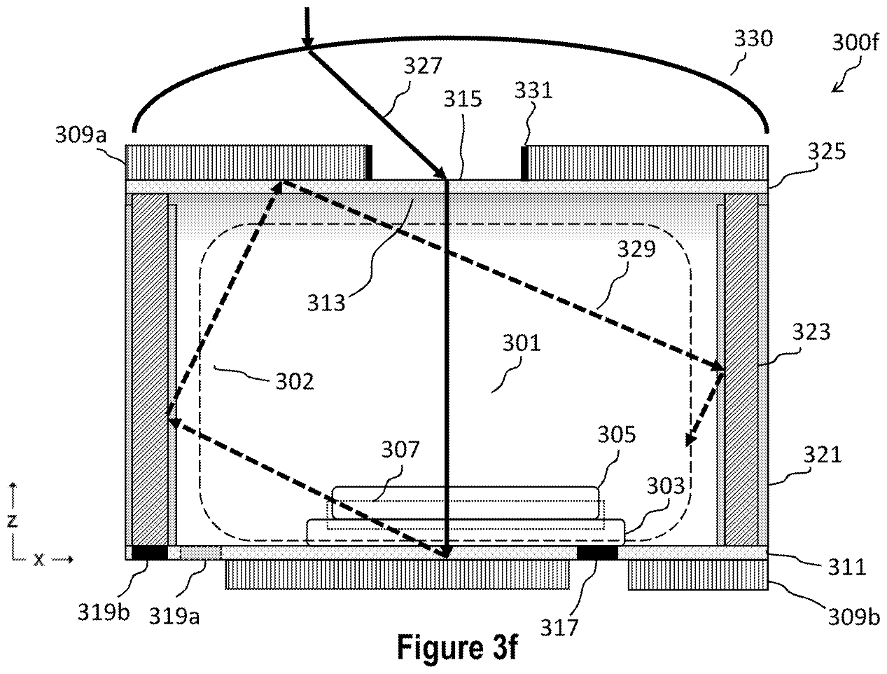

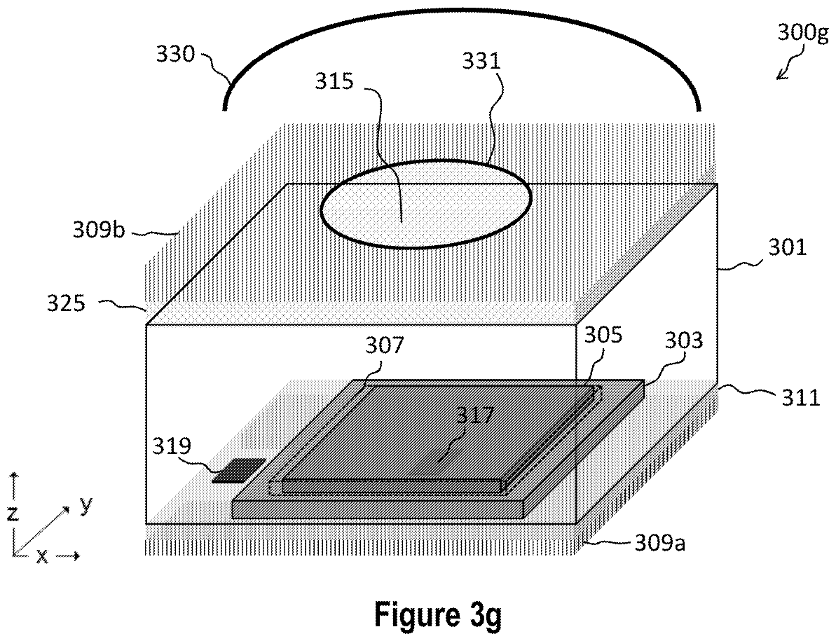

FIGS. 3a-3f illustrate optoelectronic devices according to some embodiments.

FIG. 3a illustrates an optoelectronic device 300a, in accordance with some embodiments. FIG. 3b illustrates a three dimensional (3D) plan view of the optoelectronic device 300a. The optoelectronic device 300a includes a silicon material 301, a anti-reflection layer 325, and including a first doped region 303 and a second doped 305 region associated therewith where the first doped region has a higher concentration than the second doped region and the second doped region has the same dopant type as the silicon material. During reverse bias operation, the first and second doped regions thus form a high-field junction region 307. A contact 319a provides an electrical connection to the silicon material 301 and second doped region 305. A contact 317 provides electrical connection to the first doped region 303. In one embodiment, a contact 319b provides electrical connection to the silicon material and second doped region.

Numerous configurations are contemplated, and any type of high-field junction configuration is considered to be within the present scope. For example, the first and second doped regions can be distinct from one another, contacting one another, overlapping one another, etc. In some embodiments, a lightly doped region is located at least partially between the first and second doped regions where the lightly doped region is of the same species and lower concentration than the second doped region. In some embodiments, the first doped region is an n-type silicon material and the second doped region is a p-type silicon material. In some other embodiments, the first doped region is a p-type silicon material and the second doped region is an n-type silicon material. In some embodiments the n-type dopant includes one or more of phosphorous, arsenic, antimony, or a combination thereof, and the like, and the p-type dopant comprises one or more of boron, BF₂, gallium, or a combination thereof, and the like.

The position of the high-field junction region 307 can be located anywhere in the silicon material 301. For example, the high-field region can be located adjacent to the incident light surface 315 of the device. In one embodiment, the high-field junction is located in a range of 1 micron to about 3 microns from a silicon surface. In another embodiment, the optoelectronic device is configured to preferentially avalanche electrons.

In some embodiments, the optoelectronic device includes an anti-reflection layer 325, and a reflective diffractive region 309 coupled to and separated from the silicon material 301 with a dielectric layer 311 and positioned to interact with electromagnetic radiation. In some embodiments, the reflective diffractive region is located on a side of the silicon material that is opposite the incident light surface 315 and adjacent to the high-field junction region 307. In some embodiments, the dielectric layer 311 is thin enough as to not allow light to be trapped inside this layer. The dielectric layer can be a standard layer as part of the Complementary Metal Oxide Semiconductor (CMOS) process or a custom layer designed to couple light in and out of the diffractive region.

In some embodiments the thickness of the dielectric layer is in a range from about 10 nm to about 1 micron. The dielectric layer may also constitute pairs of layers designed to provide anti-reflection properties at the silicon interface as a means to efficiently couple reflected diffracted light in and out of the silicon material. The incident electromagnetic radiation 327 that passes through the silicon material 301 contacts the diffractive reflective region 309. It is then reflected back 329 through the silicon material at a new angle making one or more additional passes at steep angles, thus effectively increasing the absorption path length in the silicon material.

In some embodiments, the angle for reflection from the reflective diffractive region allows for total internal reflection. The reflective diffractive region can be associated with an entire surface of the silicon material or only a portion thereof. Additionally, in some embodiments, the reflective diffractive region or regions can be specifically positioned to maximize the absorption path length of the silicon material. In other embodiments, a third region near, adjacent, or opposite the diffractive reflective region is included to improve the transport of photoelectric carriers to the high-field junction. The third region can comprise of a doping gradient, electric field, or any method designed to assist the carriers into the highfield junction region.

In some embodiments, the optoelectronic device comprises a backside illuminated structure. One technique for making a backside illuminated optoelectronic device includes but not limited to a starting material of epitaxially grown silicon. The process starts with a handle wafer of a high (ie. 1E19 #/cm³) doping concentration. Using atomic layer deposition or other thin-film growth techniques a desired layer thickness of silicon is grown on top of the handle wafer. During the growth process dopants are introduced to the growing material to control the resistivity of the resulting silicon layer. A result of the growth process is that there is an out diffusion of dopant atoms from the highly doped substrate into the epitaxial silicon layer. This out-diffusion creates a dopant gradient in the epitaxial silicon layer. As part of the backside process, the highly doped handle wafer is thinned to a desired thickness. It is advantageous to stop the thinning at the highly doped layer of the epitaxial silicon 313. This highly doped layer and resulting gradient serve to passivate the surface and provide an electric field to repel photoelectric carriers from the surface where they can recombine at surface interface defects and thus not be detected.

In some embodiments, the epitaxial wafer is grown with an out-diffusion gradient sufficient to allow the depletion region to extend to the incident light surface. As demonstrated in FIG. 3a, a depletion region, dashed line 302, extends through the silicon and into the out-diffusion at the edge of the highly doped region 313. This arrangement of depletion region and out-diffusion depth allows an optoelectronic device to be fully depleted and operable above breakdown providing for efficient photoelectric charge collection and increased PDE. In other embodiments, the starting material contains a buried insulator layer which separates a handle region from an active device region whereby the handle region is removed.

The silicon materials of the present disclosure can also be made using a variety of manufacturing processes. In some embodiments, the manufacturing procedures can affect the efficiency of the device and is taken into account in achieving a desired result. In some embodiments, exemplary manufacturing processes can include one or more of Czochralski (Cz) processes, magnetic Czochralski (mCz) processes, Float Zone (FZ) processes, epitaxial growth or deposition processes, silicon-on-insulator, and the like. In some embodiments, the silicon material is epitaxially grown. In some embodiments, the silicon material has a resistivity of 1,000 Ohm-cm. In some other embodiments, the silicon material has a resistivity in the range of about 100 Ohm-cm to about 500 Ohm-cm. In some embodiments, the silicon material has a resistivity in the range of 10 Ohm-cm to about 100 Ohm-cm.

FIG. 3c illustrates optoelectronic device 300c according to some embodiments. In addition to positioning reflective diffractive region or regions adjacent to the front and/or back surfaces, additional confinement of laterally propagating electromagnetic radiation 329 is enhanced with trench isolation structures. In some embodiments, as illustrated in FIG. 3c, the trench isolation comprises of an isolation layer 321 and a conductive or nonconductive fill material 323 or combination thereof. The isolation layer serves to passivate the surface against the generation of carriers which can cause increased DCR and/or isolate the conductive fill of the trench from the silicon. The trench can extend substantially from the front surface to the back surface as demonstrated in FIG. 3c. When used with a conductive fill 323 a contact 319b can provide an electrical path from the front side to the backside of the silicon material 301. Conversely, contact 319a can be used in configurations not utilizing conductive trench fill for making contact to the silicon.

In some embodiments, an isolation layer is formed by dielectric material disposed in the sidewall of the trench. The dielectric materials can be any of SiO2, SiN, HfO2, AlO2 or any combination thereof and the like. In some other embodiments, the dielectric comprises of one or more pairs of dielectric materials disposed in the sidewalls of the trench. In some embodiments, the isolation layer comprises of a shallow doped layer. In some embodiments, the trench extends from the top surface and terminates at the highly doped back region. In some other embodiments, the trench extends from a surface to an opposite surface and includes a conductive material for making electrical contact to the highly doped region 313. In some embodiments, electrical contact to the conductive fill is provided and operable with a potential difference between the silicon and the conductive fill.

FIGS. 3d-3e illustrate optoelectronic device 300d according to some embodiments. FIG. 3e illustrates a three dimensional (3D) plan view of the optoelectronic device 300d. In some embodiments, the reflective diffractive region is associated with the incident light surface 315 as illustrated in FIG. 3d. In some embodiments, the incident electromagnetic radiation, solid line 327, passes through the reflective diffractive region 309b and is coupled into the silicon material 301 at an angle, dashed lines 329, increasing the path length. In one embodiment, there is a reflective trench fill 323 and a second diffractive reflective region 309a opposite the incident surface for interacting with electromagnetic radiation that has been diffracted by the incident reflective diffractive region, 309b. The reflective trench, first and second diffractive reflective regions thus confine the electromagnetic radiation inside of the silicon material.

FIGS. 3f-3g illustrate optoelectronic device 300f, according to some embodiments. FIG. 3g illustrates a three dimensional (3D) plan view of the optoelectronic device 300d. In some embodiments, as illustrated in FIG. 3f, an optical element 330 is positioned to focus or direct incident electromagnetic radiation 327 through an aperture 331 in a reflective diffractive region 309a. In some embodiments, the optical element includes any optical element that directs, bends, or refracts electromagnetic radiation. Examples of optical elements include, but not limited to micro-lens, GRIN lens, light pipes, light funnel, a combination thereof and the like.

In some embodiments, an additional increase in the optical confinement of the optoelectronic device is realized, through the ratio of the optical collection area of the optical element to the size of the aperture. By confining all sides of the silicon material 301 using reflective trench fill 323 and reflective diffractive regions 309a and 309b which redirect the electromagnetic radiation inside the silicon material, the electromagnetic radiation can effectively be confined to the silicon material with low probability of loss, further increasing the absorption of electromagnetic radiation. In some embodiments, there is one reflective diffractive regions associated with a first incident optical surface and a second reflective diffractive region positioned the side opposite the first surface. In some embodiments, the first reflective diffractive region contains an aperture. In some embodiments, the reflective diffractive region or regions are a combination of a flat metallic region and a region containing features to redirect electromagnetic radiation contained in the same, opposite, or adjacent layers. In some embodiments, a reflective trench substantially surrounds the silicon material.

In some embodiments, the reflective diffractive region is formed by various techniques, including chemical etching (e.g. anisotropic etching, isotropic etching), nanoimprinting, additional material deposition, reactive ion etching, laser ablation, and the like.

In some embodiments, the silicon material can be of any thickness that allows for electromagnetic radiation absorption detection and conversion functionality, and thus any such thickness of silicon material is considered to be within the present scope. Although any thickness of the silicon material is considered to be within the present scope, thin silicon layer materials can be particularly beneficial in decreasing the DCR, timing jitter, and response time of the device. As has been described, photoelectric carriers can be more quickly collected from thinner silicon material layers as compared to thicker silicon material layers. For thin silicon material, there is a lower number of defects due to the decreased volume. This leads to a lower probability of a photoelectric charge carrier encountering a defect that could trap the carrier. This is particularly beneficial in high-field optoelectronic devices where a trapped carrier in the vicinity of a high-field junction can emit from the trap causing a spurious avalanche referred to as after-pulsing.

Thus one objective to implementing a low timing jitter device is to utilize a thin silicon material for the body region of the optoelectronic device. Such a device can be operated above breakdown and be nearly depleted of charge carriers by the potential bias across the terminals while also providing for optimum collection of the photoelectric charge carriers by transport at saturation velocity in an electric field. Charge carriers remaining in any undepleted region of the optoelectronic device are collected by diffusion transport, which is slower and causes increased jitter than drift transport. It is a benefit of the present disclosure that carrier transport is dominated by drift transport. A depletion region, dashed line 302, extends through the silicon and into the out-diffusion at the edge of the highly doped region 313. This arrangement of depletion region and out-diffusion depth allows an optoelectronic device to be fully depleted and operable above breakdown providing for efficient photoelectric charge collection and increased PDE. In some embodiments, the depletion region extends through the entire silicon material to the highly doped region. For this reason, it is desirable to have the thickness of any region to be such that diffusion transport is eliminated or at least minimized and/or primarily dominated by drift transport. As such, in some embodiments it can be useful to utilize a silicon material layer having a thickness of less than 20 μm. In other embodiments, the silicon material can have a thickness and substrate doping concentration such that an applied bias to the high-field junction causes full depletion of the silicon with an electrical field sufficient for saturation velocity of the photoelectric charge carriers and operation above avalanche breakdown.

Accordingly, in some embodiments the silicon material has a thickness in the range of 1 μm to 50 μm. In other embodiments, the silicon material has a thickness in the range of 1 μm to 20 μm. In some embodiments, the silicon material has a thickness in the range of 5 μm to 10 μm. In some other embodiments, the silicon material has a thickness in the range of 1 μm to 5 μm.

As has been described, high-field optoelectronic devices according to some embodiments of the present invention can exhibit lower dark count rate levels as compared to traditional high-field devices. One exemplary reason is that a thinner silicon material layer can have fewer crystalline defects responsible for the generation of carriers in or near the depletion region of a high-field junction during operation which can cause an avalanche in the absence of incident electromagnetic radiation. In addition, crystalline defects can also trap photoelectric charge and later release the trapped carrier resulting in after-pulsing. In some embodiments, for example, the dark count rate of a high-field optoelectronic device during operation is in the range of about 0.01 Hz/μm² to about 0.50 Hz/μm². In some embodiments, the maximum dark current count rate of an optoelectronic device during operation is less than 1 Hz/μm². In some embodiments, the after-pulsing probability is less than 1%. In some embodiments, the after pulse probability is less than 0.1%.

As has been described and illustrated in FIG. 3a, the reflective diffractive region can function to redirect incident electromagnetic radiation, depicted as dashed lines 329, to increase the absorption path length, thus increasing the PDE of a thin device. In some embodiments, the reflective diffractive region includes features that interact with and redirect the incident electromagnetic radiation into lateral propagating modes, dashed lines 329, that act to confine the electromagnetic radiation in the silicon material. In some embodiments, the features of the reflective diffractive region comprise one or more of cones, pyramids, pillars, protrusions, micro-lenses, quantum dots, nanoparticles, inverted features and the like. In some embodiments, factors such as manipulating the feature sizes, spacing, layer thickness, dimensions, material types, dopant profiles, feature location, allow the reflective diffractive region to be tunable for increasing the absorption of a specific wavelength or wavelength range. In some embodiments, the features in the reflective diffractive region comprise of conductive and non-conductive materials specifically designed to redirect electromagnetic radiation into lateral propagating modes in the silicon. Conductive materials consist of aluminum, tungsten, copper, gold, titanium, combinations thereof and the like. Non-conductive materials comprise of silicon dioxide, silicon nitride, hafnium oxide, aluminum oxide, combinations thereof and the like. It is within the scope of the present invention that all materials used in a CMOS process can be used for defining the features in the reflective diffractive region. In some embodiments, tuning the reflective diffractive region allows a specific wavelength or range of wavelengths to increase PDE preferentially. In some embodiments, tuning the reflective diffractive region allows specific wavelengths or ranges of wavelengths to be lossy and hence have a reduced PDE.

As has been described, a reflective diffractive region according to embodiments of the present invention allows a silicon material to experience multiple passes of incident electromagnetic radiation within the device, particularly at longer wavelengths (e.g., infrared). Such internal reflection increases the effective absorption length to be greater than the thickness of the semiconductor absorption region. This increase in absorption length increases the quantum efficiency and thus the PDE of the device, leading to an improved signal to noise ratio.

Array of Devices

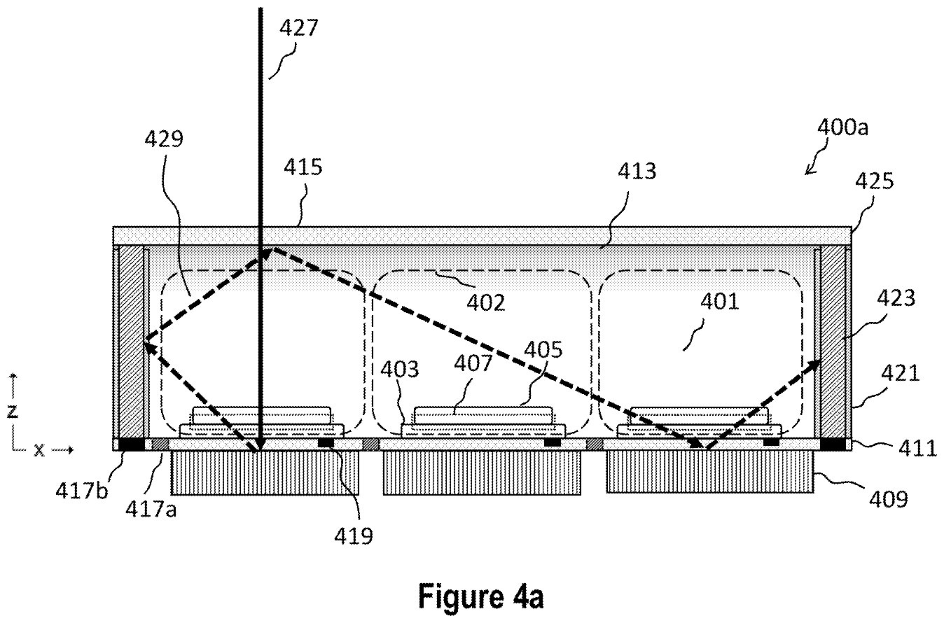

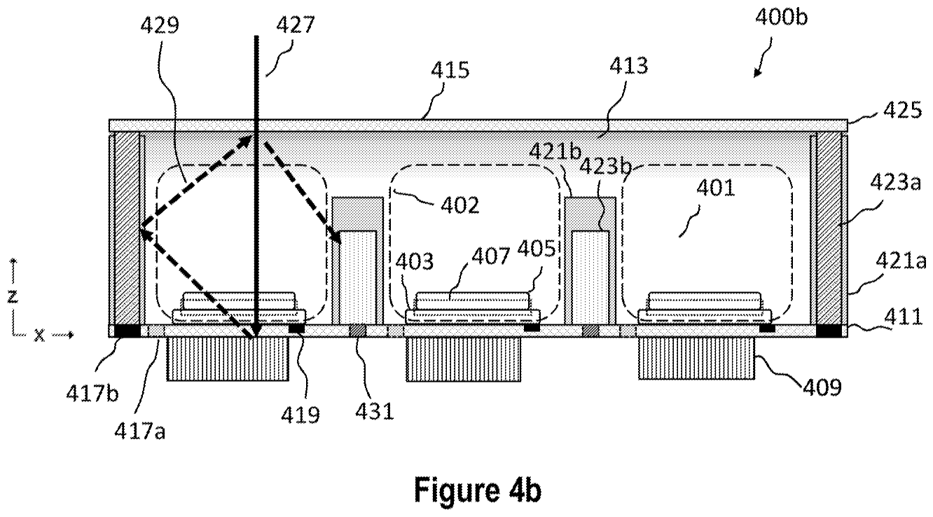

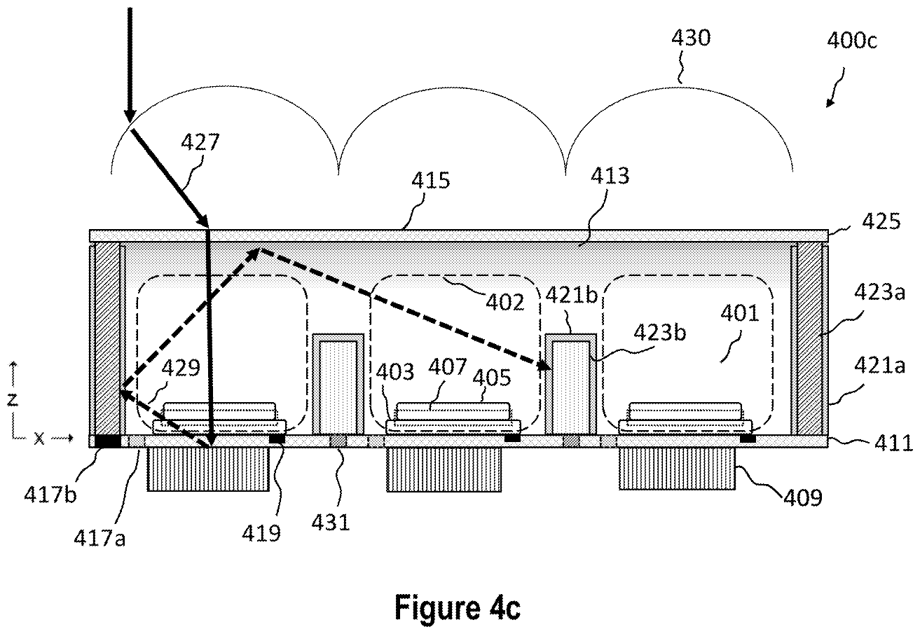

FIG. 4 illustrates an optoelectronic device array 400a in accordance with some embodiments. In some embodiments, the array 400a includes a silicon material 401 having an incident light surface 415, an anti-reflection layer 425, at least two high-field junctions in the silicon material, where each optoelectronic device in the array includes a first doped region 403 and a second doped region 405 forming a high-field junction region 407, and one or more reflective diffractive regions 409 coupled to the silicon material and positioned to interact with electromagnetic radiation. Contacts 417a provides electrical connection to the second doped region and contact 419 provides electrical contact to the first doped region 403. The optoelectronic device operable with a reverse bias voltage across the contacts.

In some embodiments, the optoelectronic device array includes a reflective diffractive region 409 coupled to and separated from the silicon material 401 with a dielectric layer 411 and positioned to interact with electromagnetic radiation. In some embodiments, the reflective diffractive region is located on a side of the silicon material that is opposite the incident light surface 415 and adjacent to the high-field junction region 407. In some embodiments, the dielectric layer 411 is thin enough as to not allow light to be trapped inside this layer. The dielectric layer can be a standard layer as part of the CMOS process or a custom layer designed to couple light in and out of the diffractive region. In some embodiments the dielectric layer is in a range from about 10 nm to about 1 micron thick. The dielectric layer may also constitute pairs of layers designed to provide anti-reflection properties at the silicon interface as a means to efficiently couple reflected diffracted light in and out of the silicon material.

The incident electromagnetic radiation 427 that passes through the silicon material contacts the diffractive reflective region. It is then reflected back 429 through the silicon material at a new angle making one or more additional passes at steep angles, thus effectively increasing the absorption path length in the silicon material. In some embodiments, the angle for reflection from the reflective diffractive region allows for total internal reflection. The reflective diffractive region can be associated with an entire surface of the silicon material or only a portion thereof.

Additionally, in some embodiments the reflective diffractive region or regions can be specifically positioned to maximize the absorption path length of the silicon material. In other embodiments, a third region near, adjacent, or opposite the diffractive reflective region is included to improve the transport of photoelectric carriers to the high-field junction. The third region can comprise of a doping gradient, electric field, or any method designed to assist the carriers into the high-field junction region. A preferred arrangement is a backside illuminated optoelectronic device structure. A technique for making a backside illuminated optoelectronic device includes but not limited to a starting material of epitaxially grown silicon.

The process starts with a handle wafer of a high (e.g., 1E19 #/cm³) doping concentration. Using atomic layer deposition or other thin-film growth techniques, a desired layer thickness of silicon is grown on top of the handle wafer. During the growth process dopants are introduced to the growing material to control the resistivity of the resulting silicon layer. A result of the growth process is that there is an out diffusion of dopant atoms from the highly doped substrate into the epitaxial silicon layer. This out diffusion creates a dopant gradient in the epitaxial silicon layer. As part of the backside process, the highly doped handle wafer is thinned to a desired thickness. It is advantageous to stop the thinning at the highly doped layer of the epitaxial silicon 413. This highly doped layer and resulting gradient serve to passivate the surface and provide an electric field to repel photoelectric carriers from the surface where they can recombine at surface interface defects and thus not be detected.

In some embodiments, the epitaxial wafer is grown with an out diffusion gradient sufficient to allow the depletion region to extend to the incident light surface. As demonstrated in FIG. 4, a depletion region, dashed line 402, extends through the silicon and into the out-diffusion at the edge of the highly doped region 413. This arrangement of depletion region and out-diffusion depth allows an optoelectronic device to be fully depleted and operable above breakdown providing for efficient photoelectric charge collection and increased PDE. In other embodiments, the starting material contains a buried insulator layer which separates a handle region from an active device region whereby the handle region is removed. In addition to positioning reflective diffractive region or regions adjacent to the front and/or back surfaces, additional confinement of laterally propagating electromagnetic radiation 429 is enhanced with trench isolation structures having reflective properties.

In some embodiments, as illustrated in FIG. 4, the trench isolation comprises of an isolation layer 421 and a conductive or non-conductive fill material 423 or combination thereof. The isolation layer serves to passivate the surface against the generation of carriers which can cause increased DCR and/or isolate the conductive fill of the trench from the silicon. The trench can extend from the front surface substantially to the back surface as demonstrated in FIG. 4. When used with a conductive fill 423 a contact 417b can provide an electrical path from the front side to the backside of the silicon material 401. Alternatively, a contact 417a can provide contact to the silicon material.

In some embodiments, an isolation layer is formed by dielectric material disposed in the sidewall of the trench. The dielectric materials can be any of SiO2, SiN, HfO2, AlO2 or any combination thereof and the like. In some other embodiments, the dielectric comprises of one or more pairs of dielectric materials disposed in the sidewalls of the trench. In some embodiments, the isolation layer comprises of a shallow doped layer. In some embodiments, the trench extends from the top surface and terminates at the highly doped back region. In some other embodiments, the trench extends from a surface to an opposite surface and includes a conductive material for making electrical contact to the highly doped region. In some embodiments, electrical contact to the conductive fill is provided and operable with a potential difference between the silicon and the conductive fill.

In some embodiments the reflective diffractive region can be a single reflective diffractive region or multiple reflective diffractive regions. In some embodiments, the optoelectronic device array has a response time in the range of about 1 picosecond to about 1 nanoseconds, and a PDE greater than or equal to about 20%, for electromagnetic radiation having at least a wavelength in the range of about 800 nm to about 1200 nm.

FIG. 4b, illustrates an optoelectronic device array 400b in accordance with some embodiments. In some embodiments, the optoelectronic device array 400b includes one or more of structures, materials and elements same as optoelectronic device array 400a, such as structures, materials and elements 401-425. As illustrated in FIG. 4b, a silicon material 401 includes at least two high-field junction regions each including a first doped region 403 and a second doped region 405 forming a high-field junction 407. A reflective diffractive region 409 is positioned to interact with electromagnetic radiation. In addition, an isolation structure 423b is positioned between the optoelectronic devices. The isolation structure 423b can be partially, as depicted, or fully through the silicon material 401. The isolation structure 423b can have a conductive fill and a contact 431 to apply a bias to repel photoelectric carriers from the interface. Conversely, when used with a nonconductive fill within the isolation structure 423b, a doped region 421b can serve to move carriers laterally to the depletion region, dashed line 402, for improved collection. In addition to the isolation structure 423b an additional isolation structure 423a may be used to surround and optical and electrically isolate an array of optoelectronic devices from an adjacent array.

FIG. 4b, illustrates an optoelectronic device array 400b in accordance with some embodiments. In some embodiments, the optoelectronic device array 400b includes one or more of structures, materials and elements same as optoelectronic device array 400a, such as structures, materials and elements 401-425. As illustrated in FIG. 4b, a silicon material 401 includes at least two high-field junction regions each including a first doped region 403 and a second doped region 405 forming a high-field junction 407. A reflective diffractive region 409 is positioned to interact with electromagnetic radiation. In addition, an isolation structure 423b is positioned between the optoelectronic devices. The isolation structure 423b can be partially, as depicted, or fully through the silicon material 401. The isolation structure 423b can have a conductive fill and a contact 431 to apply a bias to repel photoelectric carriers from the interface. Conversely, when used with a nonconductive fill within the isolation structure 423b, a doped region 421b can serve to move carriers laterally to the depletion region, dashed line 402, for improved collection. In addition to the isolation structure 423b an additional isolation structure 423a may be used to surround and optical and electrically isolate an array of optoelectronic devices from an adjacent array.

In some embodiments, as illustrated in FIG. 4c, an optical element array 430 is positioned to focus or direct incident electromagnetic radiation 427 that passes through the silicon material 401 and interacts with the diffractive reflective region 409. The light is then reflected back 429 through the silicon material at a new angle making one or more additional passes at steep angles, thus effectively increasing the absorption path length in the silicon material. In some embodiments, the angle for reflection from the reflective diffractive region allows for total internal reflection. The reflective diffractive region can be associated with an entire surface of the silicon material or only a portion thereof. In one embodiment, the reflected light 429 interacts with at least one trench isolation structure.

In some embodiments, the optical element array includes any optical element that directs, bends, or refracts electromagnetic radiation. Examples of optical elements include, but not limited to micro-lens, GRIN lens, light pipes, light funnel, a combination thereof and the like.

In some embodiments, an aperture array is formed on the incident light surface. An additional increase in the optical confinement of the optoelectronic device is realized, through the ratio of the optical collection area of the optical element to the diameter of the aperture in the aperture array. By confining all sides of the silicon material 401 using reflective trench fill 423a and reflective diffractive regions positioned on both sides of the device which redirect the electromagnetic radiation inside the silicon material, the electromagnetic radiation can effectively be confined to the silicon material with low probability of loss, further increasing the absorption of electromagnetic radiation. In some embodiments, there is one reflective diffractive regions associated with a first incident optical surface and a second reflective diffractive region positioned the side opposite the first surface. In some embodiments, the first reflective diffractive region contains an aperture. In some embodiments, the reflective diffractive region or regions are a combination of a flat metallic region and a region containing features to redirect electromagnetic radiation contained in the same, opposite, or adjacent layers. In some embodiments, a reflective trench substantially surrounds the silicon material.

Various types of isolation structures are contemplated, and any such isolation is considered to be within the present scope. In some embodiments, the isolation structure is a shallow or a deep trench isolation. In some embodiments, the isolation structure includes depths between shallow and deep isolation, depending on the device design. In some embodiments, the isolation structures include dielectric materials, reflective materials, conductive materials, and combinations thereof, including reflective diffractive features. Thus the isolation structures can be configured to redirect electromagnetic radiation, in some embodiments until it is absorbed, thereby increasing the effective absorption length of the device. In some embodiments, the isolation structures may be configured to fully or partially surround a single optoelectronic device. In some embodiments, the isolation structures may be configured to surround an array of optoelectronic devices. In some embodiments, the isolation structures are configured to surround an array of electrically coupled high-field junctions.

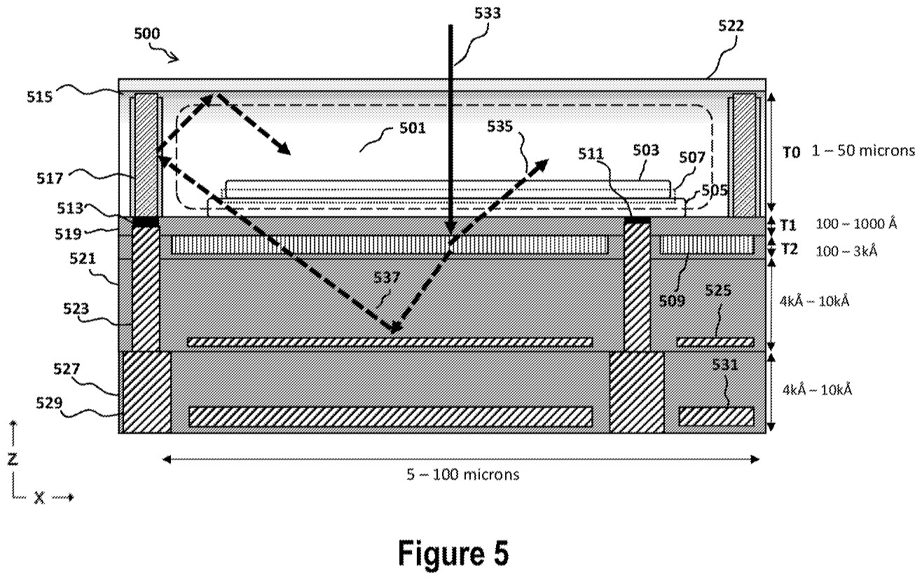

FIG. 5 illustrates optoelectronic device 500 according to some embodiments. In some embodiments, as illustrated in FIG. 5, an optoelectronic device 500 includes a silicon material 501 including a first doped region 503 and a second doped region 505 associated therewith, wherein the first and second doped regions form a high-field junction region 507. A first reflective diffractive region 509 is coupled to and separated from the silicon material with a dielectric layer and is positioned to interact with incident 533 reflected 535 electromagnetic radiation. Positioned behind the reflective diffractive region 509 is an additional second reflective diffractive region 525, as part of the BEOL, and positioned to reflect additional electromagnetic radiation 537 back into the active area of the device. In some embodiments, the optoelectronic device includes a first contact 511 to provide electrical contact to one side of the device, and a second contact 513 to provide electrical contact with the other side of the device through a conductive trench fill 517 to the highly doped region 515. In some embodiments, a contact may be provided on the same side as the first contact and connected to a via such as depicted by second contact 513. In some embodiments, the first contact and the second contact are opposite in voltage polarity from one another. In some embodiments, the first and second contacts are on the same side of the device. As illustrated in FIG. 5, the BEOL is typically a stack of 1 or more oxide 519, 521, and 527 and metal layers 525 and 531 connected with vias 523 and 529 between the layers. As demonstrated in FIG. 5 electromagnetic radiation can interact with multiple reflective diffractive regions as depicted by the dashed lines 535 with the reflective diffractive regions consisting of 1 or more BEOL layers.

In some embodiments, a reverse bias is applied across the first and second contacts. The reverse bias functions to operate the device above breakdown to increase the PDE, to decrease the timing jitter and response time of the device, by creation of an electric field sufficient to accelerate and sweep charge carriers from regions of the silicon material furthest from the high-field junction. The additional reverse bias supplied to the device above the breakdown voltage is considered an “over-voltage”. Any bias voltage capable of operating at and above the avalanche breakdown voltage is considered to be within the present scope. In some embodiments, for example, the reverse bias is in the range of 10V to 100 V. In some embodiments, the reverse bias is in the range of 20 V to 50 V. In some embodiments, the reverse bias is in the range of about 10 V to about 30 V. In a further embodiment, the reverse bias is in the range of about 10 V to about 250 V. In some other embodiments, the reverse bias is in the range of about 15V to about 30V and sufficient to accelerate carriers to saturation velocity

The applied reverse voltage bias on an optoelectronic device or device array plays an important role in defining operational characteristics of the optoelectronic device at a point or window in time. One characteristic detrimental to the detection of signals is the PDE and the DCR. The PDE defines the probability of detection of the device while the DCR defines the false alarm rate of the device. In many remote sensing applications, such as LiDAR, it is advantageous to maximize the PDE while minimizing the false alarms during an instance or window of time. As discussed herein, false alarms may be from the dark current carriers caused by crystalline defects causing DCR and after-pulsing or from ambient light. During high ambient light operation, it may be advantageous to operate the device at a desired bias for a window of time that reduces the false alarms and provides for a high probability of detection during the window of time. For this reason, desired performance can be gained by having a time dependent reverse bias across the terminals of the device. In the case of ToF LiDAR for instance, having the reverse bias at or below breakdown for the beginning of the time-of-flight reduces the probability of triggering a false alarm while having the bias at its maximum over voltage for further objects which are later in time improves sensitivity of the device to detect the lower signal returned from more distant and/or lower reflectance objects. In some embodiments, the optoelectronic device has a time dependent reverse bias voltage starting at a first voltage and ending at a second voltage over a time duration. The time duration and first and second voltage range are chosen from the measurement of a characteristic. The start of the time dependent voltage can be initiated or synchronized with the emission of one or more transmitters. In some embodiments, the bias voltage is changed from a first to a second value at a delay between the emission of the transmitter and a desired delay time. In some embodiments, the change in voltage has a linear, exponential, or quadratic relationship between the voltage and time duration. In some embodiments, the reverse bias voltage starts at about the avalanche voltage to a maximum over voltage during a time duration range from 1 ns (nanoseconds) to about 100 us (microseconds). In some embodiments, the time dependent reverse bias voltage is a step, which has a linear, exponential, or quadratic relationship between voltage steps, with each step having a time duration in a range of 1 ns to about 100 us. In some embodiments one or more steps in voltage are synchronized with the emission of the transmitter. In some embodiments, there are at least two reverse bias voltages, wherein one is about the avalanche voltage and is commanded to a second voltage over a duration of time from 1 ns to about 100 us.

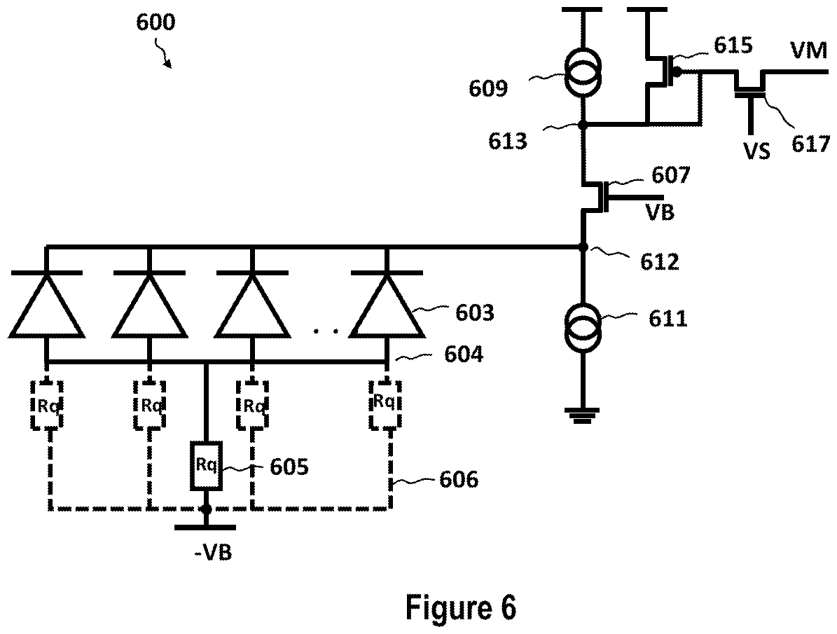

FIG. 6 illustrates an optoelectronic device array readout 600 according to some embodiments. In some embodiments it is advantageous to operate the optoelectronic device in an array, for example in the generation of 3D image, of two or more electrically and/or optically coupled pixel elements where each pixel element comprises of one or more coupled optoelectronic devices 603, as shown schematically in FIG. 6. In FIG. 6, the optoelectronic devices 603 are connected in parallel with the anodes and cathodes sharing common connections. In one example the anodes are all connected in parallel, solid line 604, and through a shared quenching resistor 605. In some embodiments, the anodes are all connected through individual resistors, shown as dashed lines 606. In some embodiments, the cathodes are connected at common connection point 612 to the source of a bias transistor 607 operated to set the input resistance and DC level at the cathode of the pixel element. The bias transistor operating point is set by the combination of high and low side current sources, schematically represented as 609 and 611 respectively. In some embodiments, the DC offsets between pixel elements in the array can be adjusted with a programmable voltage VB. In some embodiments one or both of the current sources can be shared amongst other pixel elements in the array. In another embodiment, the voltage VB is a fixed voltage. When an avalanche occurs, the avalanche current from the pixel element causes current to flow through the diode connected transistor 611 creating a voltage at node 613 proportional to the avalanche current. In this example the voltage is used to mirror the current to a later stage for additional processing. In a shared pixel element architecture it is advantageous to have the ability to multiplex or select and deselect one or more pixel elements under various operating conditions. This function is schematically shown as a select transistor 617 operable with a select voltage, VS, to enable and disable the mirrored voltage, VM.

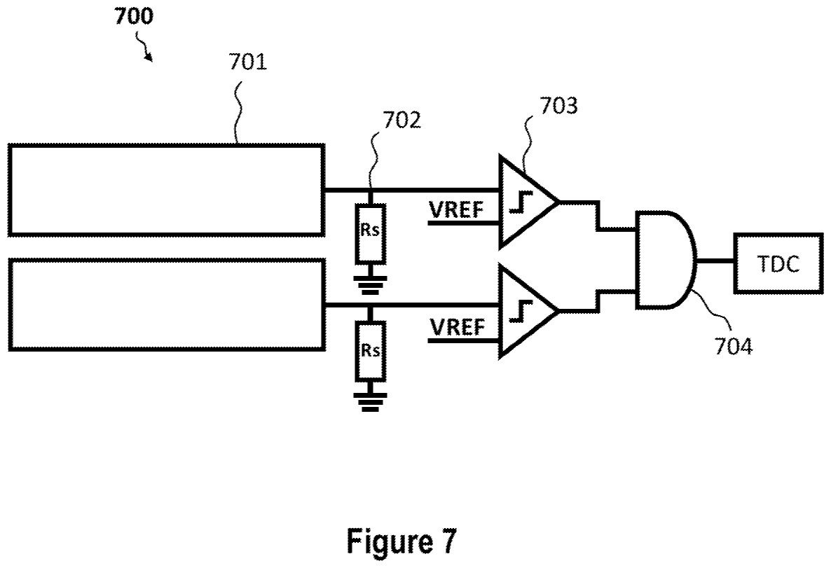

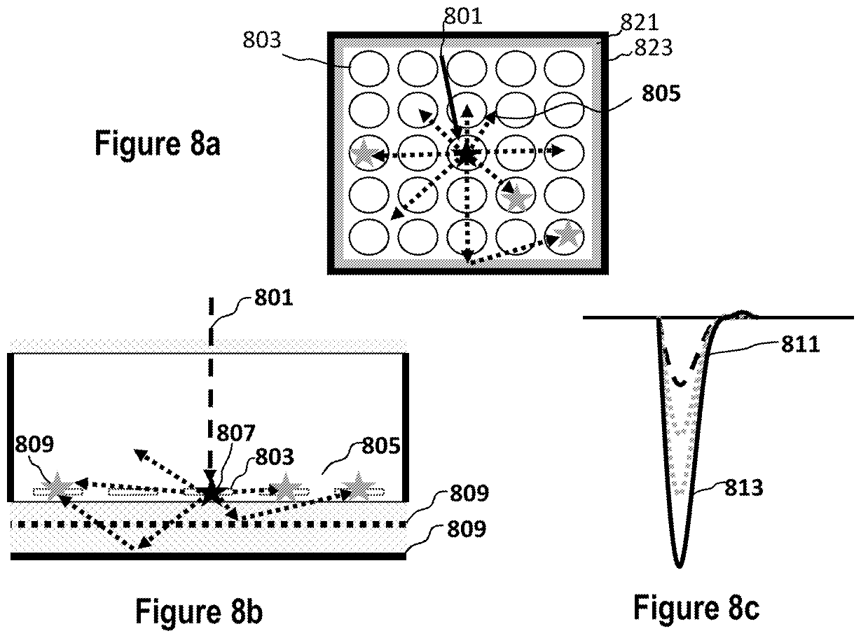

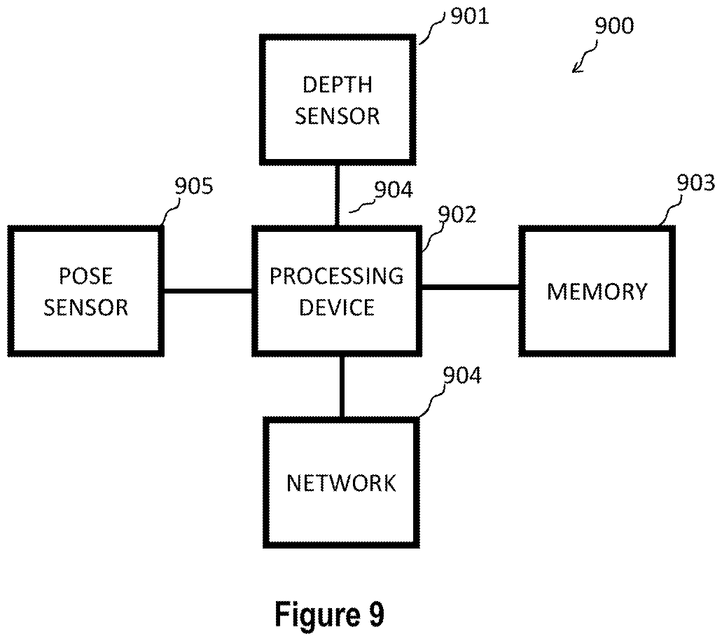

FIG. 7 illustrates an optoelectronic device array logic 700 according to some embodiments. In some embodiments, as illustrated in FIG. 7, two or more pixels elements based on the embodiments of the present invention 701 are coupled to transistors configured to drive a logic function. In some embodiments, the transistors can be configured to sense a voltage and/or current signal from the pixel element and compare that to a reference voltage or current. In some embodiments, a voltage is sensed across a sense element 702 and compared to a reference voltage. In some embodiments, the sense element comprises of one or more transistors configured to generate a voltage in response to a current, a current mirror, a resistor, or combination thereof and the like. When a signal from the sense element is above the reference voltage the circuit outputs a logic signal to the logic function 704. The logic function is one or more of a NAND, NOR, OR, or AND or any combination thereof. In some embodiments, the logic function is an AND function. In some embodiments, the logic function is formed by a three input AND function where one input is an enable signal. In some embodiments, the output of the logic function is coupled to a time-to-digital converter (TDC). In some embodiments, the logic function is operable to reduce false alarms.

FIGS. 8a-8c illustrate schematics related to avalanche events, according to some embodiments. It is one characteristic of an optoelectronic device array that during avalanche there is a finite probability that an electron will cause the emission of a secondary photon. The probability is approximately 1 in 50,000 electrons will generate a photon. This means that during a typical avalanche event where approximately one million electrons cross the junction there will be approximately 20 photons generated. FIG. 8a schematically depicts this process. The incident photon, solid line, 801 impinges on the device and causes an avalanche, black star, at a high-field junction region 803. These secondary photons, dashed lines, emit in random directions and locations from the high-field junction causing what is typically referred to as “optical cross-talk” and these photons are typically in a wavelength range of about 900 nm to about 1200 nm.

Secondary photons can travel long distances, greater than 50 microns, through the silicon material since due to the fact these photons are near-infrared wavelengths and weakly absorbed. In typical applications that utilize high-field optoelectronic devices, these secondary photons are not advantageous, and steps are taken to optically isolate neighboring devices. A benefit of some embodiments is that these secondary electrons are used to increase the output signal of an incident photon or photons. As illustrated in FIGS. 8a and 8b, the secondary photons can travel to neighboring devices, be absorbed, and initiate secondary avalanches, grey stars. The confinement and lateral propagation of secondary photons in the silicon material increases the detection probability of very low levels of incident electromagnetic radiation by increasing the output signal. In one embodiment the optoelectronic device will output about the same signal level independent of the incident signal strength.

As demonstrated in FIG. 8b a device of the various embodiments of the present invention confines the secondary photons, dashed lines, using reflective diffractive regions 809 to be absorbed in the silicon material in neighboring devices causing additional avalanches, grey stars, and consequently a multiplication of the signal. In some embodiments, an incident photon causes an initial avalanche and generates secondary photons. The secondary photons are confined with 1 or more reflective diffractive regions and cause 1 or more avalanches of one or more neighboring devices increasing the output signal. In some embodiments, the secondary photons are confined to the silicon material with a diffractive reflective region and laterally propagate and cause the avalanche of N neighboring devices causing an N multiplication of the output signal.

As previously discussed and a benefit of the present disclosure, is the use of secondary photon confinement to increase the PDE and thus the probability of detection. FIG. 8c illustrates an avalanche signal of a typical device 811 where one or more high-field devices are triggered due to incident electromagnetic radiation and an optoelectronic device in some embodiments where one or more neighboring high-field devices are triggered from secondary photons adding together, grey dashed lines, and increase the signal 813 due to the avalanche of one or more neighboring devices causing an increase in the signal output proportional to the number of avalanched devices. In some embodiments, the signal due to the avalanche generation caused by one or more secondary photons is used to measure the time-of-flight to an object. In some embodiments, reflective diffractive regions are positioned to optically couple an array of optoelectronic devices.

Various array configurations and components are contemplated, and any such should be considered to be within the present scope. In some embodiments, non-limiting examples of such components include a carrier wafer, an antireflective layer, a micro-lens array, a dielectric layer, circuitry layer, a via(s), a capacitive coupling, an infrared filter, a color filter array (CFA), an infrared cut filter, an isolation feature, and the like. In some embodiments, two or more optoelectronic devices of the present invention are configured to form an array of pixel elements.

For the array devices according to some embodiments of the present invention, a high PDE is achieved within a thin (i.e. less than 50 μm) layer of silicon material. Therefore, substantially all of the carriers generated can be collected via drift mechanism. This allows a fast charge collection and signal detection.

FIG. 9 illustrates a system for range finding according to some embodiments. As illustrated in FIG. 9, a system 900 useful for range finding, LiDAR, generating 3D depth imagery, and the like comprises of a depth sensor 901, memory 903, a network interface 904, and a pose sensor 905 each connected to one or more processing devices 602. The optical elements of the depth sensor 901 configured using the present embodiments and capable of providing data to a processing device 902 over a data bus, solid line 904.

In some embodiments, the data includes one or more of: a range to one or more objects, depth, magnitude, X-Y position, object movement, time-of-flight, interrupts, alarms, triggers, thresholds, or a combination thereof and the like. In some embodiments, one or more memory elements are coupled to one or more processing systems over a memory bus. In some embodiments, the data stored in the memory includes but not limited to range, user data, magnitude, variables, operating code, and a combination thereof and the like. Any type of memory is considered including DRAM, SRAM, flash, embedded flash, block memory, magnetic, and combinations and the like. In some embodiments, one or more pose sensors 905 are provided and connected to one or more processing systems through a data bus, solid line.

The pose sensors are operable to measure the angle, rotations, orientation, and accelerations of the system. The pose sensors comprise of one or more of accelerometers, gyroscopes, magnetometers, pressure sensors, image sensors, or a combination thereof. In some embodiments, the pose sensor comprises of one or more image sensors operable to output the relative orientation and/or changes in the orientation of the system. In some embodiments, one or more network interfaces 904 are provided allowing for data to be transmitted. The network interfaces receive data over a data bus, solid line, from one or more processing devices. The network interfaces are operable over wired and/or wireless communication protocols. Wired communications include serial, Low-voltage differential signaling (LDVS), or any communications conducted over a wired medium and the like. Wireless communications include protocols such as Bluetooth, WiFi, Infra-red (IR), or any communications conducted over wireless medium and the like. In some embodiments, the system is configured to provide data from the network interfaces, the data comprising of depth and texture. In some embodiments, the system is configured and operable to provide depth and orientation data. In some embodiments, the system is configured and operable to provide synchronized depth and orientation data where the synchronization is determined by one or more master clocks.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

However, the above embodiments are not limited in this regard and, in various implementations, the above embodiments may include the undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

1-29. (canceled)

30. An optoelectronic device, comprising:
a silicon material including a first doped region and a second doped region forming a high-field junction region;
a reflective diffractive region coupled to and separated from the silicon material with a dielectric layer and positioned to interact with electromagnetic radiation;
a backside illuminated structure; and
an optical element positioned to focus or direct incident electromagnetic radiation through an aperture in the reflective diffractive region.

31. The optoelectronic device of claim 30, wherein the first doped region has a higher con-centration than the second doped region and the second doped region has the same dopant type as the silicon material.

32. The optoelectronic device of claim 30, wherein a lightly doped region is located at least partially between the first and second doped regions, wherein the lightly doped region is the same species and lower concentration than the second doped region.

33. The optoelectronic device of claim 30, wherein the first doped region is an n-type silicon material and the second doped region is a p-type silicon material.

34. The optoelectronic device of claim 30, wherein the first doped region is a p-type silicon material and the second doped region is an n-type silicon material.

35. The optoelectronic device of claim 30, wherein the n-type dopant includes one or more of phosphorous, arsenic, or antimony.

36. The optoelectronic device of claim 30, wherein the p-type dopant comprises one or more of boron, BF2, or gallium.
